(19) United States
(12) Patent Application Publication
(10) Pub. No.: US 2022/0319600 A1
(43) Pub. Date: Oct. 6, 2022

(54) THREE-DIMENSIONAL FLASH MEMORY AIMED AT INTEGRATION, AND METHOD FOR MANUFACTURING SAME

(71) Applicants: Industry-University Cooperation Foundation Hanyang University (IUCF-HYU), Seoul (KR); PeDiSem Co. Ltd., Seoul (KR)

(72) Inventors: Yun Heub SONG, Seoul (KR); Inho NAM, Seoul (KR)

(73) Assignees: Industry-University Cooperation Foundation Hanyang University (IUCF-HYU), Seoul (KR); PeDiSem Co. Ltd., Seoul (KR)

(21) Appl. No.: 17/636,910

(22) PCT Filed: Jun. 26, 2020
(86) PCT No.: PCT/KR2020/008359

§ 371 Date: Feb. 21, 2022

(30) Foreign Application Priority Data
Aug. 20, 2019 (KR) 10-2019-0101720

(51) Int. Cl. G11C 16/04; H01L 27/11556; H01L 27/11582

(52) U.S. Cl. CPC G11C 16/0483; H01L 27/11556; H01L 27/11582

(57) ABSTRACT

Disclosed are a three-dimensional flash memory aimed at integration, and a method for manufacturing same. According to an embodiment, a three-dimensional flash memory comprises: multiple memory cell strings formed on a substrate so as to extend in a direction, each of the multiple memory cell strings comprising a channel layer and an electric charge storage layer surrounding the channel layer; multiple word lines connected perpendicularly to the multiple memory cell strings; and at least one intermediate wire layer formed at an intermediate point with regard to the direction in which the multiple memory cell strings are formed to extend, the at least one intermediate wire layer being selectively available as a source electrode or as a drain electrode with regard to each of the multiple memory cell strings. At least one of the multiple memory cell strings is formed in a free area secured among the multiple word lines as a result of inclusion of the at least one intermediate wire layer in the three-dimensional flash memory.

### TECHNICAL FIELD

The following embodiments relate to a three-dimensional flash memory, and more particularly, to a three-dimensional flash memory aimed at integration and a method of manufacturing the same.

### BACKGROUND ART

A flash memory is an electrically erasable programmable read only memory (EEPROM) which electrically controls input and output of data by means of Fowler-Nordheim tunneling or hot electron injection.

In recent years, a three-dimensional structure in which cells are vertically stacked to increase the degree of integration has been applied to the flash memory in order to satisfy high performance and low price required by consumers. Referring to FIG. 1 illustrating a three-dimensional flash memory according to the related art, a three-dimensional flash memory 100 has a structure including a memory cell string 110 formed vertically, the memory cell string 110 including a channel layer 111 and a charge storage layer 112 formed to surround the channel layer 111, a plurality of electrode layers 120 connected vertically with respect to the memory cell string 110, and a plurality of insulation layers 130 alternately interposed between the plurality of electrode layers. Hereinafter, since each of the plurality of electrode layers 120 is used as a word line, the plurality of electrode layers 120 are described as a plurality of word lines 120.

Here, since contacts to be connected to an external wiring should be formed in the plurality of word lines 120, the plurality of word lines 120 form a step shape as illustrated in the drawing.

In this case, an upper wiring layer included in the three-dimensional flash memory 100 is disposed in a remaining region 121 except for the step shape formed by the plurality of word lines 120, and due to this structural problem, the memory cell string 110 has a limit in that the memory cell string 110 is formed only in a lower region 121 of the upper wiring layer 140.

Accordingly, the three-dimensional flash memory 100 has a disadvantage in that integration is degraded due to a limitation in which the region 121 in which the memory cell string 110 is formed is limited.

Therefore, a technology for overcoming the disadvantage of the three-dimensional flash memory 100 according to the related art needs to be proposed.

### DETAILED DESCRIPTION OF THE INVENTION

### Technical Problem

Embodiments propose a three-dimensional flash memory and a method of manufacturing the same, which overcome the limitation of forming a memory cell string due to a structural problem of the three-dimensional flash memory including only an upper wiring layer and a lower wiring layer.

In more detail, embodiments also propose a three-dimensional flash memory and a method of manufacturing the same in which an intermediate wiring layer is included, a spare region located between the intermediate wiring layer and the lower wiring layer is secured from a plurality of word lines, the memory cell string is formed in the spare region, and thus integration is aimed.

Further, embodiments also propose a method of manufacturing a three-dimensional flash memory which simplifies a manufacturing process by reducing the number of repeated etching processes on the word lines in a structure in which the memory cell string is formed in the spare region secured as the intermediate layer is included.

In detail, embodiments also propose a method of manufacturing a three-dimensional flash memory in which, after a plurality of word lines are prepared and divided into an upper word line group and a lower word line group that are sequentially stacked in a step shape, an etching process is simultaneously performed on the upper word line group and the lower word line group, and thus the number of repeated etching processes on the word line is significantly reduced.

### Technical Solution

According to an embodiment, a three-dimensional flash memory aimed at integration includes a plurality of memory cell strings formed on a substrate to extend in one direction, each of the plurality of memory cell strings including a channel layer and a charge storage layer surrounding the channel layer, a plurality of word lines perpendicularly connected to the plurality of memory cell strings, and at least one intermediate wiring layer that is formed at an intermediate point in a direction in which the plurality of memory cell strings extend and is selectively used as one of a source electrode and a drain electrode for each of the plurality of memory cell strings, wherein at least one memory cell string among the plurality of memory cell strings is formed in a spare region secured from the plurality of word lines as the at least one intermediate wiring layer is included in the three-dimensional flash memory.

According to an aspect, the spare region may be a region located between the at least one intermediate wiring layer and a lower wiring layer in the plurality of word lines, the lower wiring layer being a wiring layer located below each of the plurality of memory cell strings.

According to another aspect, the at least one memory cell string formed in the spare region may use the at least one intermediate wiring layer and the lower wiring layer as the source electrode and the drain electrode, respectively.

According to still another aspect, at least one memory cell string other than the at least one memory cell string formed in the spare region among the plurality of memory cell strings may use an upper wiring layer located above each of the plurality of memory cell strings and the at least one intermediate wiring layer as the source electrode and the drain electrode, respectively.

According to an embodiment, a method of manufacturing a three-dimensional flash memory aimed at integration includes preparing a semiconductor structure in which a plurality of word lines and a plurality of insulation layers are alternately stacked, at least one intermediate wiring layer is interposed, the at least one intermediate wiring layer being selectively used as one of a source electrode and a drain electrode, and a plurality of memory cell strings extend in one direction, each of the plurality of memory cell strings including a channel layer and a charge storage layer surrounding the channel layer, and performing an etching process on the semiconductor structure so that the plurality of word lines have a step shape, wherein the preparing of the semiconductor structure includes preparing the semiconductor structure in which, as the at least one intermediate wiring layer is included in the three-dimensional flash memory, at least one memory cell string among the plurality of memory cell strings is formed even in a spare region secured from the plurality of word lines.

According to an aspect, the preparing of the semiconductor structure in which the at least one memory cell string is formed may include preparing the semiconductor structure in which the at least one memory cell string is formed in the spare region located between a part of the at least one intermediate wiring layer, which remains after the etching process, and a lower wiring layer included in the three-dimensional flash memory.

According to an embodiment, a method of manufacturing a three-dimensional flash memory aimed at integration includes preparing a semiconductor structure in which a plurality of memory cell strings extend in one direction, each of the plurality of memory cell strings including a channel layer and a charge storage layer surrounding the channel layer, and a plurality of word lines alternately stacked with a plurality of insulation layers are divided into an upper word line group and a lower word line group by at least one intermediate wiring layer, the at least one intermediate wiring layer being selectively used as any one of a source electrode or a drain electrode, and the upper word line group and the lower word line group being sequentially stacked in a step shape while having different horizontal sizes so that at least partial upper surfaces thereof are expose, and simultaneously performing an etching process on the upper word line group and the lower word line group on the semiconductor structure, wherein the preparing of the semiconductor structure includes preparing the semiconductor structure in which, as the at least one intermediate wiring layer is included in the three-dimensional flash memory, at least one memory cell string among the plurality of memory cell strings is formed even in a spare region secured from the plurality of word lines.

According to an aspect, the preparing of the semiconductor structure in which the at least one memory cell string is formed may include preparing the semiconductor structure in which the at least one memory cell string is formed in the spare region located between a part of the at least one intermediate wiring layer, which remains after the etching process, and a lower wiring layer included in the three-dimensional flash memory.

According to another aspect, the lower word line group may have a larger horizontal size than that of the upper word line group.

According to still another aspect, the simultaneously performing of the etching process may be repeatedly performed based on the number of stacked word lines included in the upper word line group and the number of stacked word lines included in the lower word line group.

### Advantageous Effects of the Invention

Embodiments may propose a three-dimensional flash memory and a method of manufacturing the same, which overcome the limitation of forming a memory cell string due to a structural problem of the three-dimensional flash memory including only an upper wiring layer and a lower wiring layer.

In more detail, embodiments may also propose a three-dimensional flash memory and a method of manufacturing the same in which an intermediate wiring layer is included, a spare region located between the intermediate wiring layer and the lower wiring layer is secured from a plurality of word lines, the memory cell string is formed in the spare region, and thus integration is aimed.

Further, embodiments may also propose a method of manufacturing a three-dimensional flash memory which simplifies a manufacturing process by reducing the number of repeated etching processes on the word lines in a structure in which the memory cell string is formed in the spare region secured as the intermediate layer is included.

In detail, embodiments may also propose a method of manufacturing a three-dimensional flash memory in which, after a plurality of word lines are prepared and divided into an upper word line group and a lower word line group that are sequentially stacked in a step shape, an etching process is simultaneously performed on the upper word line group and the lower word line group, and thus the number of repeated etching processes on the word line is significantly reduced.

### DESCRIPTION OF THE DRAWINGS

FIG. 1 is a cross-sectional view illustrating a three-dimensional flash memory according to the related art.

FIG. 2 is a cross-sectional view illustrating a three-dimensional flash memory according to an embodiment.

FIG. 3 is a top view illustrating the three-dimensional flash memory according to the embodiment.

FIG. 4 is a flowchart illustrating a method of manufacturing a three-dimensional flash memory according to the embodiment.

FIGS. 5A to 5I are cross-sectional views for describing the method of manufacturing a three-dimensional flash memory according to the embodiment.

FIG. 6 is a flowchart illustrating a method of manufacturing a three-dimensional flash memory according to another embodiment.

FIGS. 7A to 7E are cross-sectional views for describing the method of manufacturing a three-dimensional flash memory according to another embodiment.

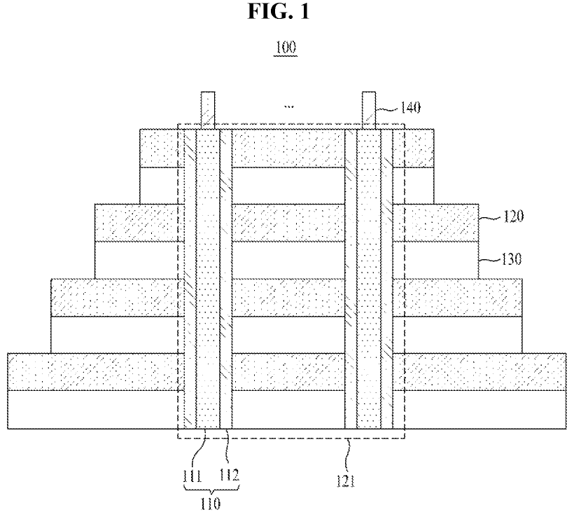

### BEST MODE

Hereinafter, embodiments will be described in detail with reference to the accompanying drawings. However, the present invention is not restricted or limited by the embodiments. Further, the same reference numerals in each drawing indicate the same components.

Further, terms used in the present specification are used to properly express the embodiments of the present invention, and the terms may change depending on the intention of a user or an operator or customs in the field to which the present invention belongs. Therefore, definitions of the present terms should be made based on the contents throughout the present specification.

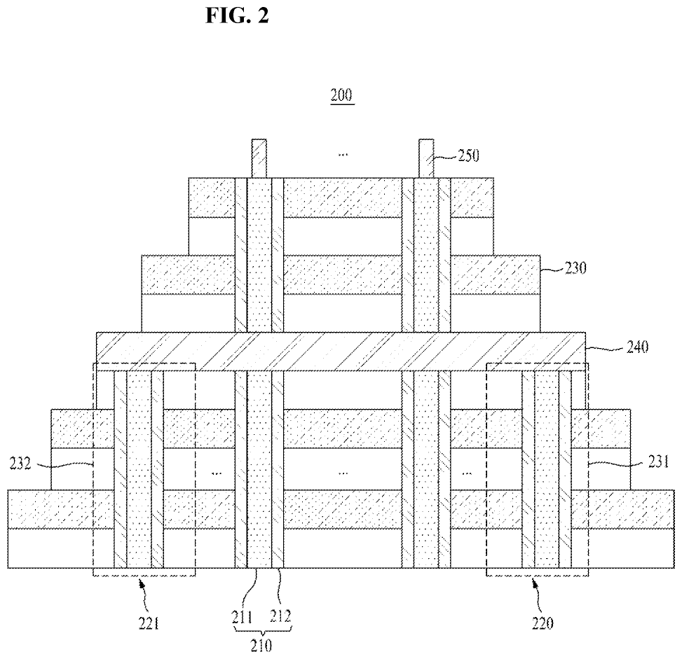

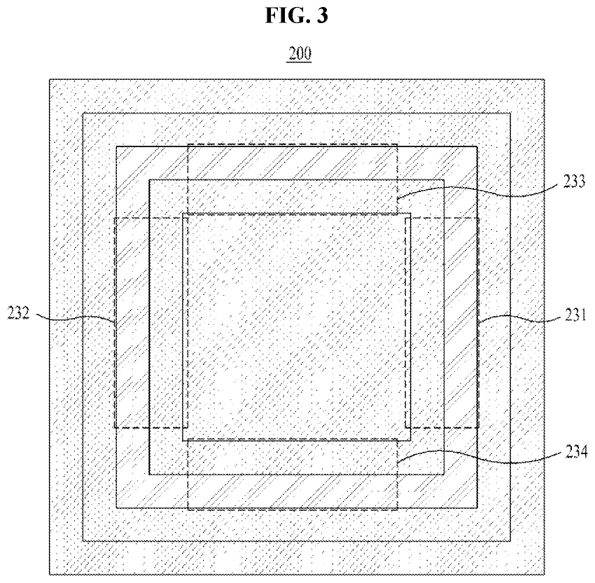

FIG. 2 is a cross-sectional view illustrating a three-dimensional flash memory according to an embodiment, and FIG. 3 is a top view illustrating the three-dimensional flash memory according to the embodiment.

Referring to FIGS. 2 and 3, a three-dimensional flash memory 200 according to the embodiment includes a plurality of memory cell strings 210, 220, and 221, a plurality of word lines 230, and at least one intermediate wiring layer 240.

Each of the plurality of memory cell strings 210, 220, and 221 extends in one direction (for example, in a vertical direction) on a substrate (not illustrated) and may include a channel layer 211 and a charge storage layer 212 surrounding the channel layer. However, the present invention is not limited or restricted thereto, and each of the plurality of memory cell strings 210, 220, and 221 may further include, as the channel layer 211 extends in the form of a hollow tube, a buried film (not illustrated) filled in the hollow tube. The channel layer 211 may be formed of single crystal silicon or polycrystalline silicon to vertically extend and may be formed by a selective epitaxial growth process, a phase transition epitaxial process, or the like using a substrate as a seed. The charge storage layer 212 is a component having a memory function of storing charges from currents flowing through the plurality of word lines 230 and may be formed of, for example, an oxide-nitride-oxide (ONO) structure. Hereinafter, it will be described that the charge storage layer 212 includes only a vertical element, but the present invention is not limited or restricted thereto, and the charge storage layer 212 may further include a horizontal element.

Further, although not illustrated in the drawings, a plurality of tunneling insulation layers (not illustrated) that surround the plurality of memory cell strings 210, 220, and 221 and extend vertically may be arranged outside the plurality of memory cell strings 210, 220, and 221. Each of the plurality of tunneling insulation layers may be formed of an insulation material having high dielectric characteristics (for example, an insulation material such as Al₂O₃, HfO₂, TiO₂, La₂O₅, BaZrO₃, Ta₂O₅, ZrO₂, Gd₂O₃, or Y₂O₃).

The plurality of word lines 230 may be perpendicularly connected to the plurality of memory cell strings 210, 220, and 221 and may be formed of a conductive material such as W, Ti, Ta, Cu, or Au to serve to apply voltages to the plurality of memory cell strings 210, 220, and 221. Here, the plurality of word lines 230 may extend to have different lengths to form a step shape.

The at least one intermediate wiring layer 240 may be formed at an intermediate point in a direction in which the plurality of memory cell strings 210, 220, and 221 extend and may be selectively used as any one of a source electrode or drain electrode of each of the plurality of memory cell strings 210, 220, and 221.

For example, when an upper wiring layer 250 is used as the source electrode, the at least one intermediate wiring layer 240 that is closest to the upper wiring layer 250 with a memory cell to be controlled interposed between the at least one intermediate wiring layer 240 and the upper wiring layer 250 may be used as the drain electrode, and when the upper wiring layer 250 is used as the drain electrode, the at least one intermediate wiring layer 240 that is closest to the upper wiring layer 250 with the memory cell to be controlled interposed between the at least one intermediate wiring layer 240 and the upper wiring layer 250 may be used as the source electrode. Hereinafter, the memory cell means a partial region of the charge storage layer 212 that is an information storage element of the three-dimensional flash memory 200 and an electrode layer (one word line of the plurality of word lines 230) that is direct contact with the partial region of the charge storage layer 212. Accordingly, the three-dimensional flash memory according to the embodiment may include the plurality of word lines 230 and thus may include a plurality of memory cells formed by pairing the plurality of word lines 230 and regions of the charge storage layer 212.

As another example, when the at least one intermediate wiring layer 240 is implemented in plurality including a first intermediate wiring layer, a second intermediate wiring layer, and a third intermediate wiring layer (when the first intermediate wiring layer, the second intermediate wiring layer, and the third intermediate wiring layer are sequentially arranged in this order), as the first intermediate wiring layer is used as the drain electrode, the second intermediate wiring layer closest to the first intermediate wiring layer with the memory cell to be controlled interposed between the first intermediate wiring layer and the second intermediate wiring layer may be used as the source electrode. Further, as the third intermediate wiring layer is used as the source electrode, the second intermediate wiring layer closest to the third intermediate wiring layer with the memory cell to be controlled interposed between the second intermediate wiring layer and the third intermediate wiring layer may be used as the drain electrode. In this way, the second intermediate wiring layer may be used as the source electrode or the drain electrode depending on whether another adjacent intermediate wiring layer is used as the drain electrode or the source electrode.

That is, each of the upper wiring layer 250 and the at least one intermediate wiring layer 240 may be adaptively used as one except for the other one of the drain electrode and the source electrode used by another wiring layer depending on whether another adjacent wiring layer with the memory cell to be controlled interposed therebetween is used as the other one of the drain electrode and the source electrode. Similarly, a lower wiring layer (wiring layer located below each of the plurality of memory cell strings 210, 220, and 221 and generally extending to cover up to the lowermost word line of the plurality of word lines 230 although not illustrated) may also be adaptively used as one except for the other one of the drain electrode and the source electrode used by another wiring layer depending on whether another adjacent wiring layer with the memory cell to be controlled interposed between the lower wiring layer and the at least one intermediate wiring layer 240 is used as the other one of the drain electrode and the source electrode.

Hereinafter, a state in which one wiring layer is used as the drain electrode or the source electrode in some cases means that corresponding wiring layer is formed to be reconfigurable so that the wiring may be adaptively used as either the source electrode or the drain electrode. Accordingly, the at least one intermediate wiring layer 240 as well as the upper wiring layer 250 and the lower wiring layer may be formed to be reconfigurable.

In the three-dimensional flash memory 200 having such a structure, at least one memory cell string 220 and 221 of the plurality of memory cell strings 210, 220, and 221 is formed in spare regions 231, 232, 233, and 234. Hereinafter, the spare regions 231, 232, 233, and 234 mean regions secured from the plurality of word lines 230 as the at least one intermediate wiring layer 240 is included in the three-dimensional flash memory 200 and mean regions of the plurality of word lines 230 located between the at least one intermediate wiring layer 240 and the lower wiring layer.

Thus, in the at least one memory cell string 220 and 221 formed in the spare regions 231, 232, 233, and 234, the at least one intermediate wiring layer 240 and the lower wiring layer may be used as the source electrode and the drain electrode, respectively.

That is, in a three-dimensional flash memory according to the related art including only the upper wiring layer 250 and the lower wiring layer without including the at least one intermediate wiring layer 240, when the memory cell strings are formed in regions corresponding to the spare regions 231, 232, 233, and 234 of the three-dimensional flash memory 200 according to the embodiment, only the lower wiring layer may be used, and thus the corresponding memory cell strings cannot be operated.

On the other hand, as described above, in the three-dimensional flash memory 200 according to the embodiment of the present invention, the at least one memory cell string 220 and 221 formed in the spare regions 231, 232, 233, and 234 may use the at least one intermediate wiring layer 240 and the lower wiring layer as the source electrode and the drain electrode, respectively.

In this case, at least one remaining memory cell string 210 of the plurality of memory cell strings 210, 220, and 221 except for the at least one memory cell string 220 and 221 formed in the spare regions 231, 232, 233, and 234 may use the upper wiring layer 250 and the at least one intermediate wiring layer 240 as the source electrode and the drain electrode, respectively.

As described above, referring to FIG. 3, the plurality of word lines 230 are illustrated to extend in all direction, but the present invention is not limited or restricted thereto, and the plurality of word lines 230 extend in only one direction so that a step shape is formed on only one side or extend in only opposite directions so that a step shape is formed on only opposite sides.

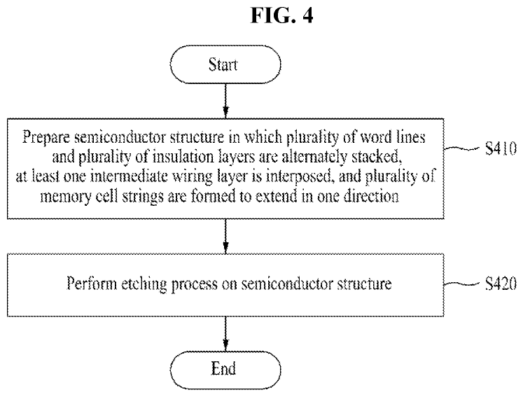

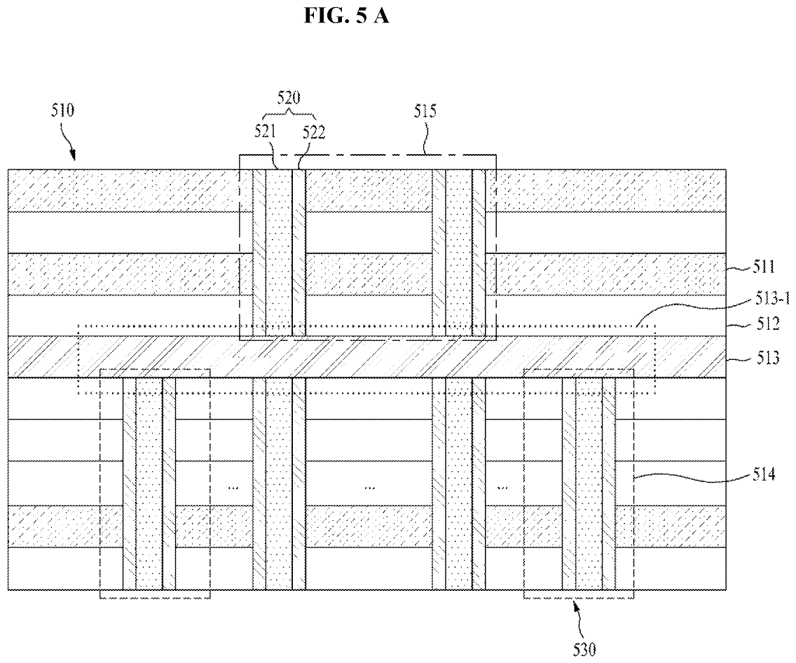

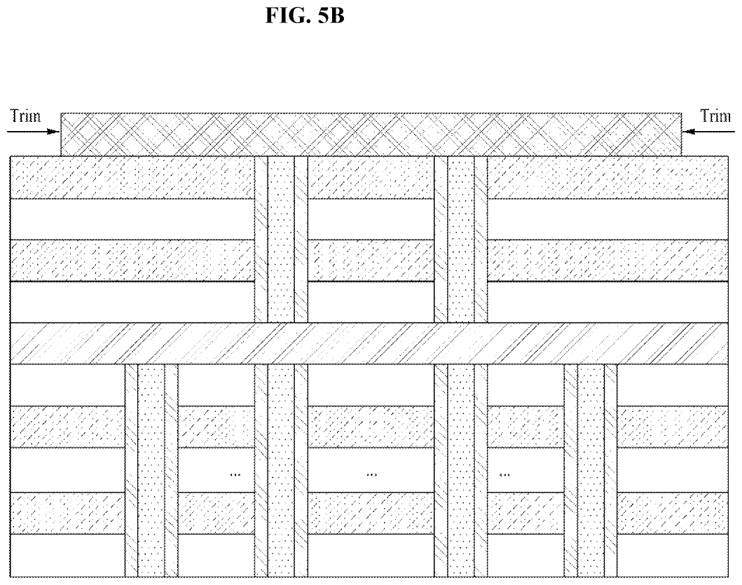

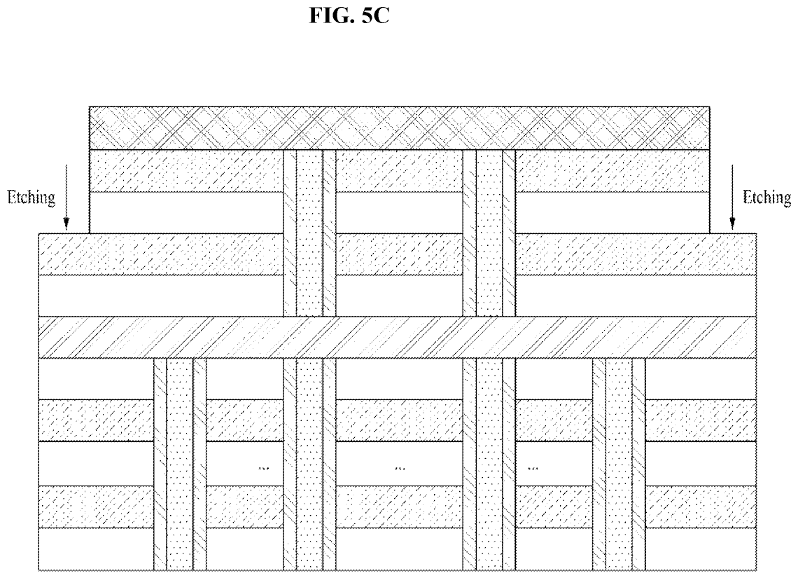

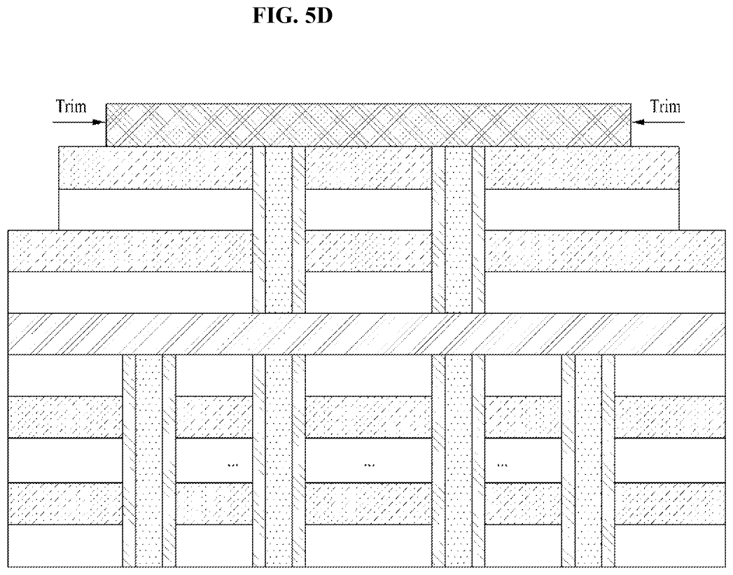

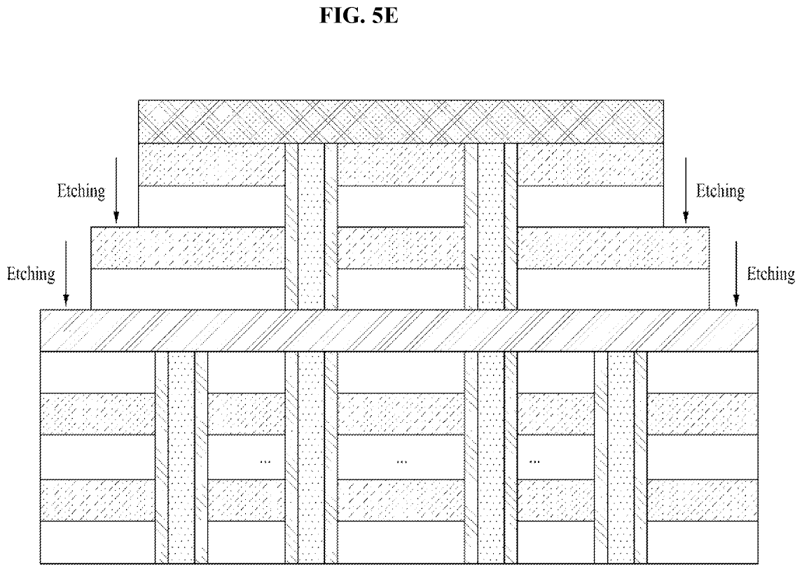

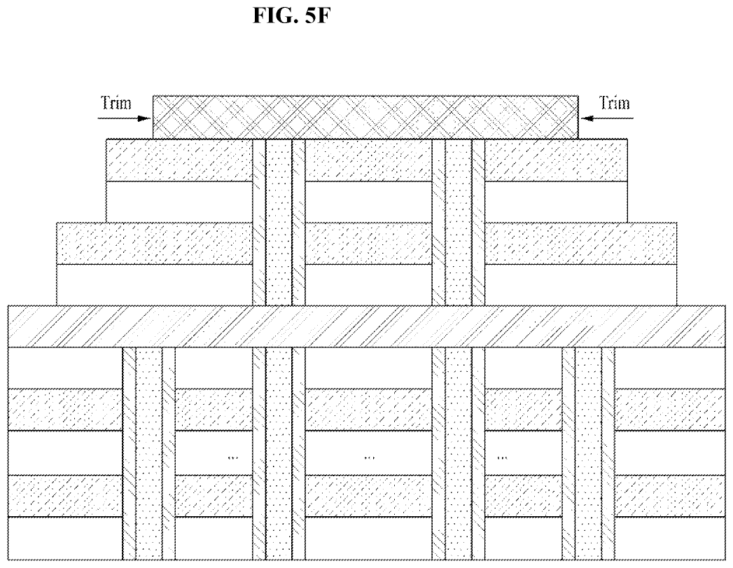

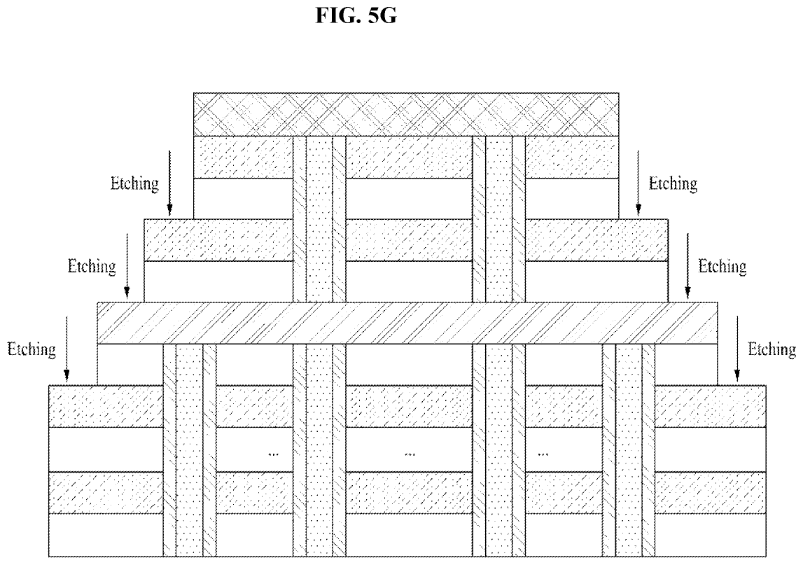

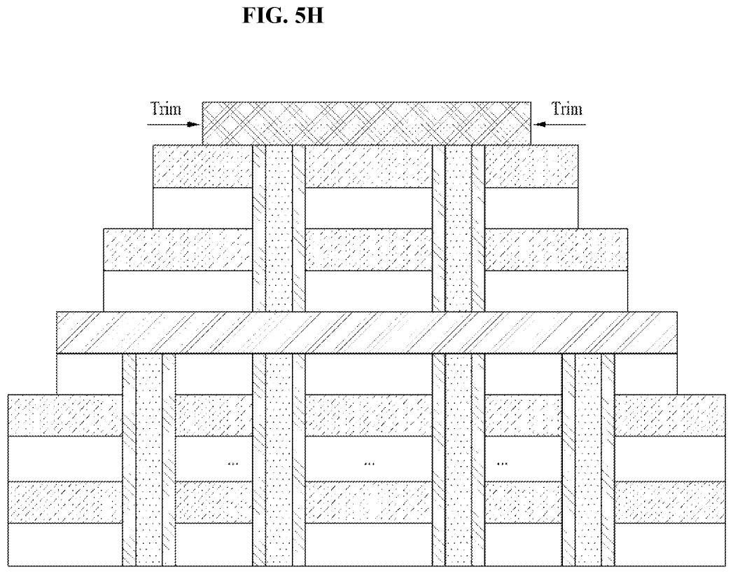

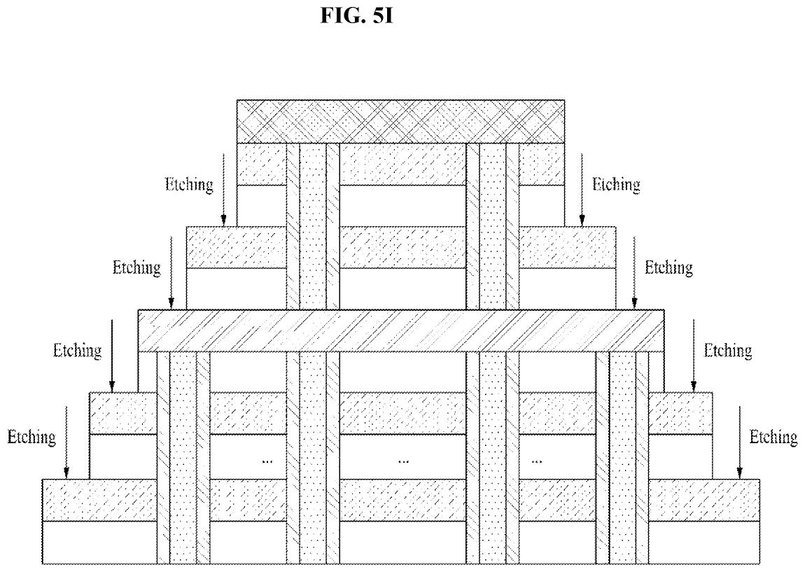

FIG. 4 is a flowchart illustrating a method of manufacturing a three-dimensional flash memory according to the embodiment, and FIGS. 5A to 5I are cross-sectional views for describing the method of manufacturing a three-dimensional flash memory according to the embodiment. Hereinafter, an automated and mechanized manufacturing system may be used as a subject for performing the method of manufacturing a three-dimensional flash memory.

Referring to FIGS. 4 to 5I, in the manufacturing system, in operation S410, as illustrated in FIG. 5A, a semiconductor structure 510 is prepared in which a plurality of word lines 511 and a plurality of insulation layers 512 are alternately stacked, at least one intermediate wiring layer 513 (the at least one intermediate wiring layer 513 may be selectively used as the source electrode or the drain electrode) is interposed between structures in which the word lines 511 and the insulation layers 512 are alternately stacked, and a plurality of memory cell strings 520 and 530 (each of the plurality of memory cell strings 520 and 530 includes a channel layer 521 and a charge storage layer 522 surrounding the channel layer 521) extend in one direction.

In this case, in the semiconductor structure 510, at least one memory cell string 530 is formed in a spare region 514 located between a part 513-1 of the at least one intermediate wiring layer 513, which remains after an etching process S420, which will be described below, and a lower wiring layer (a wiring layer located below each of the plurality of memory cell strings 520 and 530 and generally extending to cover up to the lowermost word line of the plurality of word lines 511 although not illustrated).

Further, in the semiconductor structure 510, the remaining at least one memory cell string 520 may be formed in a region 515 corresponding to the upper wiring layer.

Thereafter, in the manufacturing system, in operation S420, the etching process is performed on the semiconductor structure 510 so that the plurality of word lines 511 have a step shape as illustrated in FIGS. 5B to 5I. In this case, operation S420 may be repeatedly performed on the basis of the number of the plurality of stacked word lines 511 so that the plurality of word lines 511 may form the step shape. As illustrated in FIGS. 5B to 5I, the etching process may include a process of trimming and etching a photoresist.

Through operations S410 to S420, as the three-dimensional flash memory described with reference to FIGS. 2 to 3 is completely manufactured, the at least one memory cell string 530 is formed even in the spare region 514, and thus high integration may be achieved.

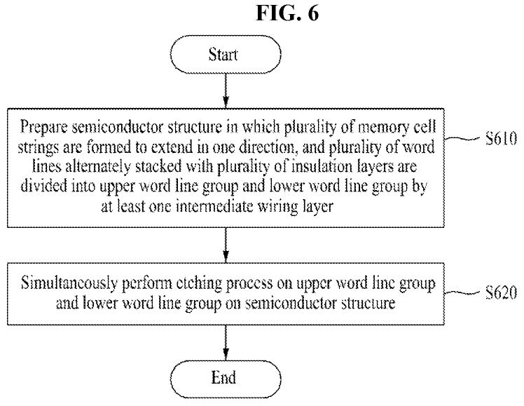

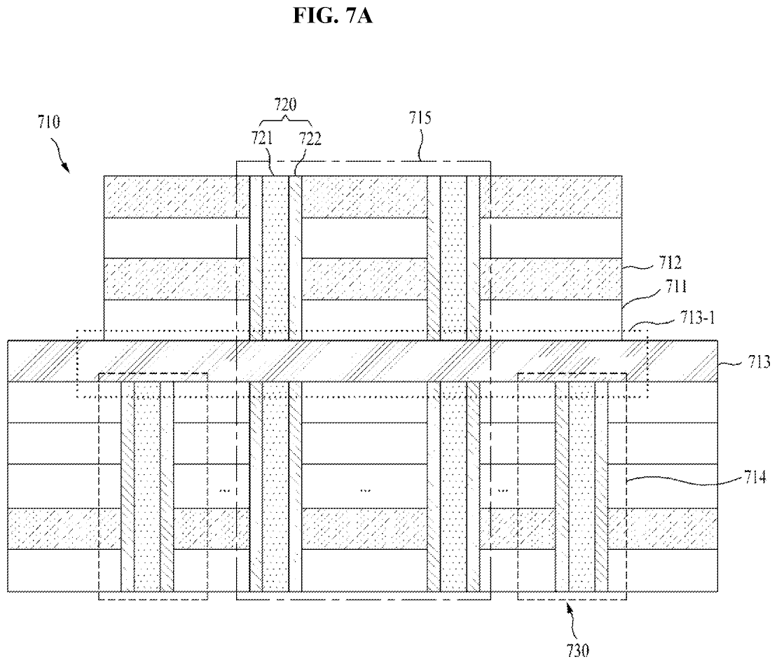

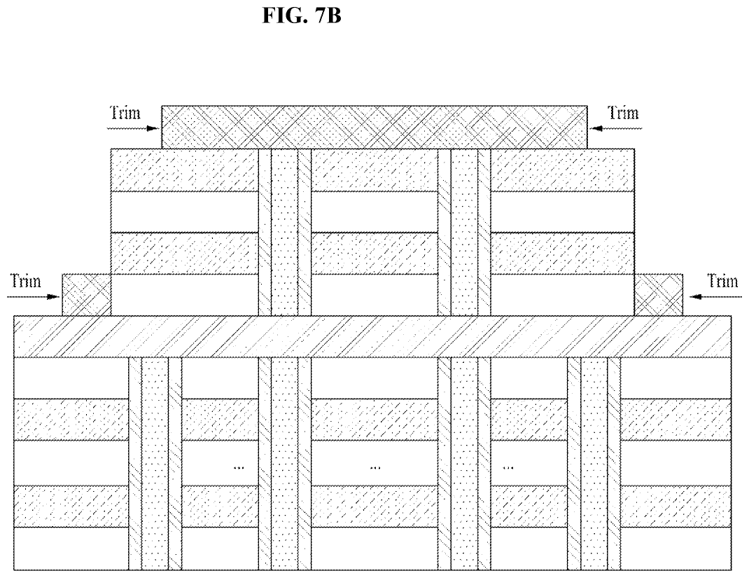

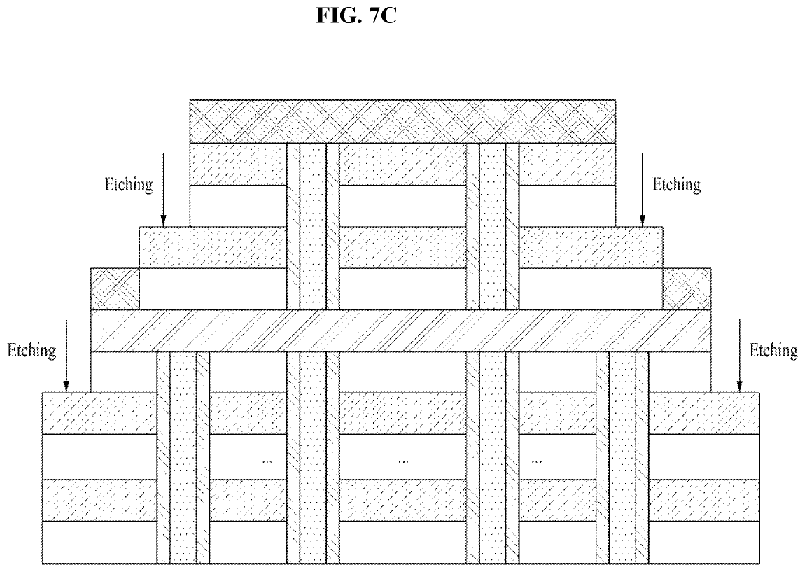

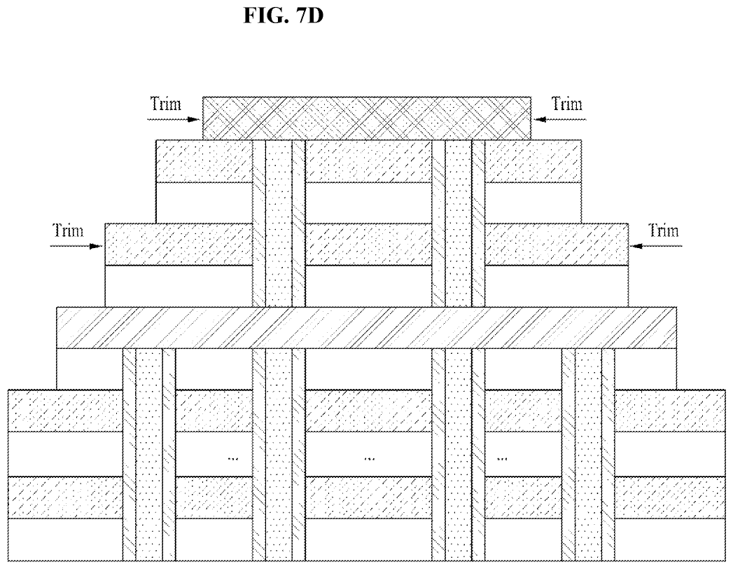

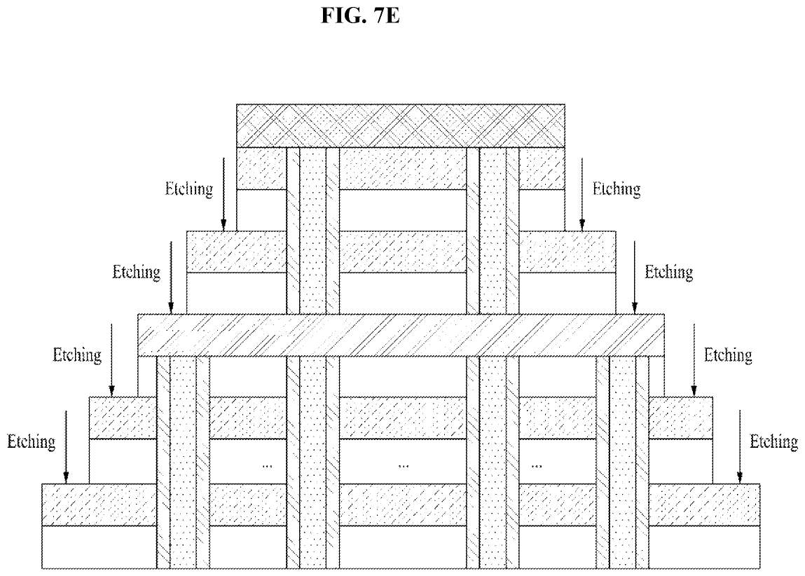

FIG. 6 is a flowchart illustrating a method of manufacturing a three-dimensional flash memory according to another embodiment, and FIG. 7A to 7E are cross-sectional views for describing the method of manufacturing a three-dimensional flash memory according to another embodiment. Hereinafter, an automated and mechanized manufacturing system may be used as a subject for performing the method of manufacturing a three-dimensional flash memory.

Referring to FIGS. 6 to 7E, in the manufacturing system, in operation S610, as illustrated in FIG. 7A, a semiconductor structure 710 is prepared in which a plurality of memory cell strings 720 and 730 (each of the plurality of memory cell strings 720 and 730 includes a channel layer 721 and a charge storage layer 722 surrounding the channel layer 721) extend in one direction and a plurality of word lines 712 alternately stacked with a plurality of insulation layers 711 are divided into an upper word line group 710-1 and a lower word line group 710-2 by at least one intermediate wiring layer 713 (the at least one intermediate wiring layer 713 may be selectively used as one of the source electrode or the drain electrode).

Here, the upper word line group 710-1 and the lower word line group 710-2 are sequentially stacked in a step shape while having different horizontal sizes so that at least partial upper surfaces thereof are exposed. For example, as the lower word line group 710-2 has a larger horizontal size than that of the upper word line group 710-1, when the upper word line group 710-1 and the lower word line group 710-2 are stacked, the at least partial upper surface of the lower word line group 710-2 may be exposed, and at the same time, the at least partial upper surface of the upper word line group 710-1 may be also exposed.

In this case, in the semiconductor structure 710, at least one memory cell string 730 is formed in a spare region 714 located between a part 713-1 of the at least one intermediate wiring layer 713, which remains after an etching process S620, which will be described below, and a lower wiring layer (a wiring layer located below each of the plurality of memory cell strings 720 and 730 and generally extending to cover up to the lowermost word line of the plurality of word lines 712 although not illustrated).

Further, in the semiconductor structure 710, the remaining at least one memory cell string 720 may be formed in a region 715 corresponding to the upper wiring layer.

Thereafter, in the manufacturing system, in operation S620, the etching process are simultaneously performed on the upper word line group 710-1 and the lower word line group 710-2 on the semiconductor structure 710 so that the plurality of word lines 712 have a step shape as illustrated in FIGS. 7B to 7E. In this case, operation S620 is repeatedly performed on the basis of the number of stacked word lines included in the upper word line group 710-1 and the number of stacked word lines included in the lower word line group 710-2, and thus the plurality of word lines 712 may form the step shape. For example, when the number of stacked word lines included in the upper word line group 710-1 is the same as the number of stacked word lines included in the lower word line group 710-2, operation S620 may be repeatedly performed the same number of times as the number of stacked word lines included in the upper word line group 710-1 (or the number of stacked word lines included in the lower word line group 710-2). As illustrated in FIGS. 7B to 7E, the etching process may include a process of trimming and etching a photoresist.

Since this etching process is repeatedly performed the number of times reduced by half as compared to operation S420 described above with reference to FIGS. 4 to 5I, a manufacturing process may be simplified.

Through operations S610 to 620, as the three-dimensional flash memory described with reference to FIGS. 2 to 3 is completely manufactured, the at least one memory cell string 730 is formed even in the spare region 714, and thus high integration may be achieved.

As described above, although the embodiments have been described with reference to the limited embodiments and the limited drawings, various modifications and changes may be made based on the above description by those skilled in the art. For example, even though the described technologies are performed in an order different from the described method, and/or the described components such as a system, a structure, a device, and a circuit are coupled or combined in a form different from the described method or are replaced or substituted by other components or equivalents, appropriate results may be achieved.

Therefore, other implementations, other embodiments, and those equivalent to the appended claims also belong to the scope of the appended claims.

1. A three-dimensional flash memory aimed at integration comprising:
a plurality of memory cell strings formed on a substrate to extend in one direction, each of the plurality of memory cell strings including a channel layer and a charge storage layer surrounding the channel layer;
a plurality of word lines perpendicularly connected to the plurality of memory cell strings; and
at least one intermediate wiring layer that is formed at an intermediate point in a direction in which the plurality of memory cell strings extend and is selectively used as one of a source electrode and a drain electrode for each of the plurality of memory cell strings,
wherein at least one memory cell string among the plurality of memory cell strings is formed in a spare region secured from the plurality of word lines as the at least one intermediate wiring layer is included in the three-dimensional flash memory.

2. The three-dimensional flash memory of claim 1, wherein the spare region is a region located between the at least one intermediate wiring layer and a lower wiring layer in the plurality of word lines, the lower wiring layer being a wiring layer located below each of the plurality of memory cell strings.

3. The three-dimensional flash memory of claim 2, wherein the at least one memory cell string formed in the spare region uses the at least one intermediate wiring layer and the lower wiring layer as the source electrode and the drain electrode, respectively.

4. The three-dimensional flash memory of claim 2, wherein at least one memory cell string other than the at least one memory cell string formed in the spare region among the plurality of memory cell strings uses an upper wiring layer located above each of the plurality of memory cell strings and the at least one intermediate wiring layer as the source electrode and the drain electrode, respectively.

5. A method of manufacturing a three-dimensional flash memory aimed at integration, the method comprising:
preparing a semiconductor structure in which a plurality of word lines and a plurality of insulation layers are alternately stacked, at least one intermediate wiring layer is interposed, the at least one intermediate wiring layer being selectively used as one of a source electrode and a drain electrode, and a plurality of memory cell strings extend in one direction, each of the plurality of memory cell strings including a channel layer and a charge storage layer surrounding the channel layer; and
performing an etching process on the semiconductor structure so that the plurality of word lines have a step shape,
wherein the preparing of the semiconductor structure includes preparing the semiconductor structure in which, as the at least one intermediate wiring layer is included in the three-dimensional flash memory, at least one memory cell string among the plurality of memory cell strings is formed even in a spare region secured from the plurality of word lines.

6. The method of claim 5, wherein the preparing of the semiconductor structure in which the at least one memory cell string is formed includes preparing the semiconductor structure in which the at least one memory cell string is formed in the spare region located between a part of the at least one intermediate wiring layer, which remains after the etching process, and a lower wiring layer included in the three-dimensional flash memory.

7. A method of manufacturing a three-dimensional flash memory aimed at integration, the method comprising:
preparing a semiconductor structure in which a plurality of memory cell strings extend in one direction, each of the plurality of memory cell strings including a channel layer and a charge storage layer surrounding the channel layer, and a plurality of word lines alternately stacked with a plurality of insulation layers are divided into an upper word line group and a lower word line group by at least one intermediate wiring layer, the at least one intermediate wiring layer being selectively used as any one of a source electrode or a drain electrode, and the upper word line group and the lower word line group being sequentially stacked in a step shape while having different horizontal sizes so that at least partial upper surfaces thereof are expose; and
simultaneously performing an etching process on the upper word line group and the lower word line group on the semiconductor structure,
wherein the preparing of the semiconductor structure includes preparing the semiconductor structure in which, as the at least one intermediate wiring layer is included in the three-dimensional flash memory, at least one memory cell string among the plurality of memory cell strings is formed even in a spare region secured from the plurality of word lines.

8. The method of claim 7, wherein the preparing of the semiconductor structure in which the at least one memory cell string is formed includes preparing the semiconductor structure in which the at least one memory cell string is formed in the spare region located between a part of the at least one intermediate wiring layer, which remains after the etching process, and a lower wiring layer included in the three-dimensional flash memory.

9. The method of claim 7, wherein the lower word line group has a larger horizontal size than that of the upper word line group.

10. The method of claim 7, wherein the simultaneously performing of the etching process is repeatedly performed based on the number of stacked word lines included in the upper word line group and the number of stacked word lines included in the lower word line group.
